(19) United States
(12) Patent Application Publication
(10) Pub. No.: US 2020/0251395 A1
(43) Pub. Date: Aug. 6, 2020

(54) ELECTRONIC STRUCTURE AND MANUFACTURING METHOD THEREOF

(71) Applicant: Siliconware Precision Industries Co., Ltd., Taichung (TW)

(72) Inventors: Chih-Chiang He, Taichung (TW); Yu-Wei Yeh, Taichung (TW); Chia-Yang Chen, Taichung (TW); Chih-Yi Liao, Taichung (TW); Chih-Hsien Chiu, Taichung (TW); Chang-Chao Su, Taichung (TW)

(21) Appl. No.: 16/460,766

(22) Filed: Jul. 2, 2019

(30) Foreign Application Priority Data
Feb. 1, 2019 (TW) 108104185

(51) Int. Cl. H01L 23/31; H01L 23/498

(52) U.S. Cl. CPC H01L 23/3128; H01L 23/5383; H01L 23/49816

(57) ABSTRACT

An electronic structure and a method for fabricating the same are provided. An electronic component and conductive elements are disposed on a carrier. An encapsulating layer encapsulates the electronic component and the conductive elements. The encapsulating layer is formed with recessed portions corresponding in position to the conductive elements. A gap is formed between the conductive elements and the recessed portions.

### BACKGROUND

### 1. Technical Field

The present disclosure relates to semiconductor packaging processes, and, more particularly, to an electronic structure and a method for fabricating the same.

### 2. Description of the Prior Art

In recent years, with the rapid development of portable electronic products, various corresponding products have also been developed in terms of high density, high performance, co pact-size and low-profile. The various semiconductor packaging structures have also been developed accordingly to meet the requirements of compact-size, low-profile and high density.

FIG. 1 is a cross-sectional view of a semiconductor packaging structure 1 according to the prior art. In the semiconductor packaging structure 1, semiconductor elements 11 and passive elements 11′ are disposed on upper and lower sides of a substrate 10, a molding compound 14 encapsulates the semiconductor elements 11 and the passive elements 11′, contacts (I/O) 100 of the substrate 10 are exposed from holes 140a of the molding compound 14 in a TMV (through mold via) manner, and a plurality of solder balls 13 are disposed on the contacts 100. In a subsequent process, the semiconductor packaging structure 1 can be mounted with an electronic device (not shown), such as a circuit board, via the solder balls 13.

In the semiconductor packaging structure 1, the holes 140a of the molding compound 14 penetrate the molding compound 14 by a laser ablation. However, the laser ablation costs high, and is likely to generate small waste pieces. As a result, the solder balls 13 cannot be bonded to the contacts 100 effectively, and are likely to be separated from the contacts 100, thereby raising the problem of low solder balls placement yield.

Therefore, how to solve the problems of the prior art is becoming an urgent issue in the art.

### SUMMARY

In view of the problems of the prior art, the present disclosure provides an electronic structure, comprising: a carrier; at least one electronic component mounted on and electrically connected to the carrier; a plurality of conductive elements bonded onto the carrier; and an encapsulating layer formed on the carrier, encapsulating the electronic component, and formed with a plurality of recessed portions corresponding in position to the plurality of conductive elements for receiving the plurality of conductive elements, wherein the plurality of conductive elements have a plurality of protruding portions protruding from an outer surface of the encapsulating layer, a gap is formed between each of the plurality of conductive elements and one of the recessed portions corresponding thereto, and each of the plurality of recessed portions has a wall shaped substantially circular arc.

The present disclosure further provides a method for fabricating an electronic structure, comprising: providing at least one electronic component on a carrier and electrically connecting the electronic component to the carrier; forming a plurality of conductive elements on the carrier; forming on the carrier an encapsulating layer that encapsulates the electronic component and the plurality of conductive elements; removing a portion of the encapsulating layer and a portion of the plurality of conductive elements, allowing one end surface of each of the plurality of conductive elements to be exposed from the encapsulating layer; and performing a reflow process, allowing the plurality of conductive elements to be formed with a plurality of protruding portions that protrude from an outer surface of the encapsulating layer, and the encapsulating layer to be formed with a plurality of recessed portions corresponding in position to the plurality of conductive elements, a gap is formed between each of the plurality of conductive elements and one of the recessed portions corresponding thereto, and each of the plurality of recessed portions has a wall shaped substantially circular arc.

In an embodiment, the carrier has a first side and a second side opposing the first side, and the encapsulating layer and the plurality of conductive elements are disposed on the first side and/or the second side.

In an embodiment, the conductive elements are in partial or no contact with the encapsulating layer.

In an embodiment, the wall of each of the recessed portions is substantially a ball surface.

In an embodiment, each of the recessed portions is in the shape of an undercut at an outer edge of the encapsulating layer.

In an embodiment, a circuit board or a packaging structure is further bonded to the protruding portions of the plurality of conductive elements.

It is known from the above that in the electronic structure and the method for fabricating the same according to the present disclosure, since the plurality of conductive elements have the plurality of protruding portions protruding from the outer surface of the encapsulating layer due to the cohesion of the conductive elements through a reflow process, for an external electronic device to be mounted thereon, the fabricating process is simplified, cost is reduced, and the conductive elements can be prevented from being separated from the contacts.

### BRIEF DESCRIPTION OF THE DRAWINGS

The disclosure can be more fully understood by reading the following detailed description of the embodiments, with reference made to the accompanying drawings, wherein:

FIG. 1 is a cross-sectional view of a semiconductor packaging structure according to the prior art;

FIGS. 2A to 2E are cross-sectional views illustrating a method for fabricating an electronic structure according to the present disclosure;

FIG. 2A′ is another aspect of FIG. 2A;

FIG. 2D′ is a locally enlarged view of FIG. 2D;

FIG. 2D″ is another aspect of FIG. 2D′;

FIG. 2F is a cross-sectional view of an electronic structure of another aspect according to the present disclosure;

FIG. 3 is a cross-sectional view of an electronic structure of another aspect according to the present disclosure;

FIG. 4 is a cross-sectional view of an electronic structure of another aspect according to the present disclosure;

FIG. 5A is a cross-sectional view of an electronic structure of another aspect according to the present disclosure; and

FIG. 5B is another application aspect of FIG. 5A.

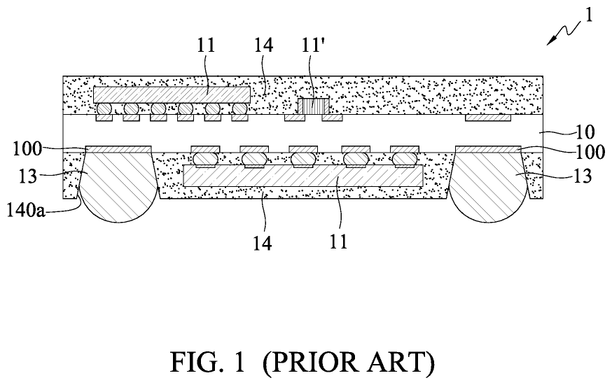

### DETAILED DESCRIPTION

The following illustrative embodiments are provided to illustrate the disclosure of the present disclosure, these and other advantages and effects can be apparently understood by those in the art after reading the disclosure of this specification. The present disclosure can also be performed or applied by other different embodiments. The details of the specification may be on the basis of different points and applications, and numerous modifications and variations can be devised without departing from the spirit of the present disclosure.

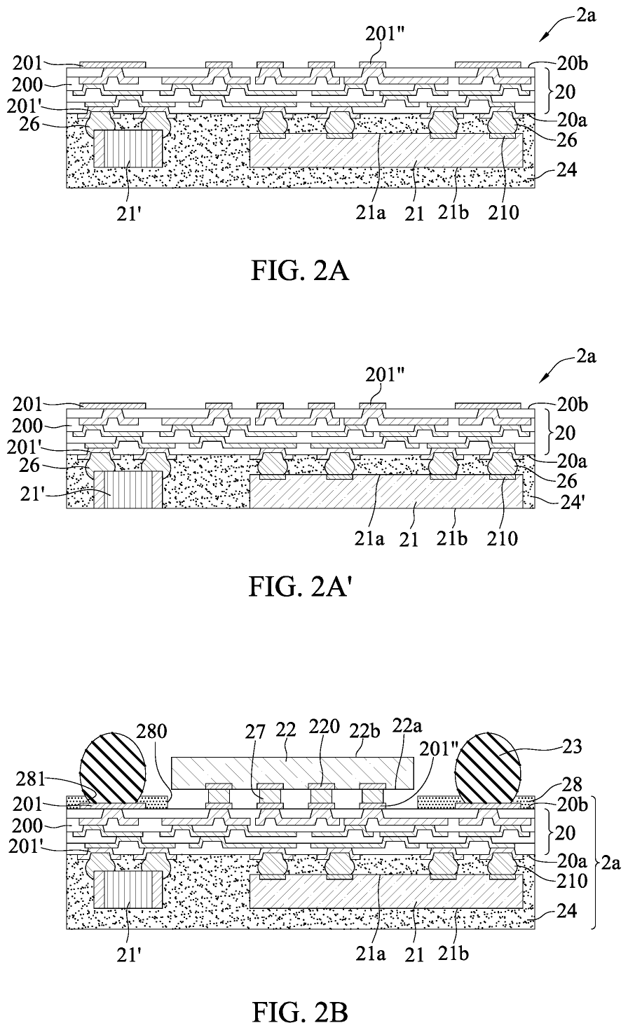

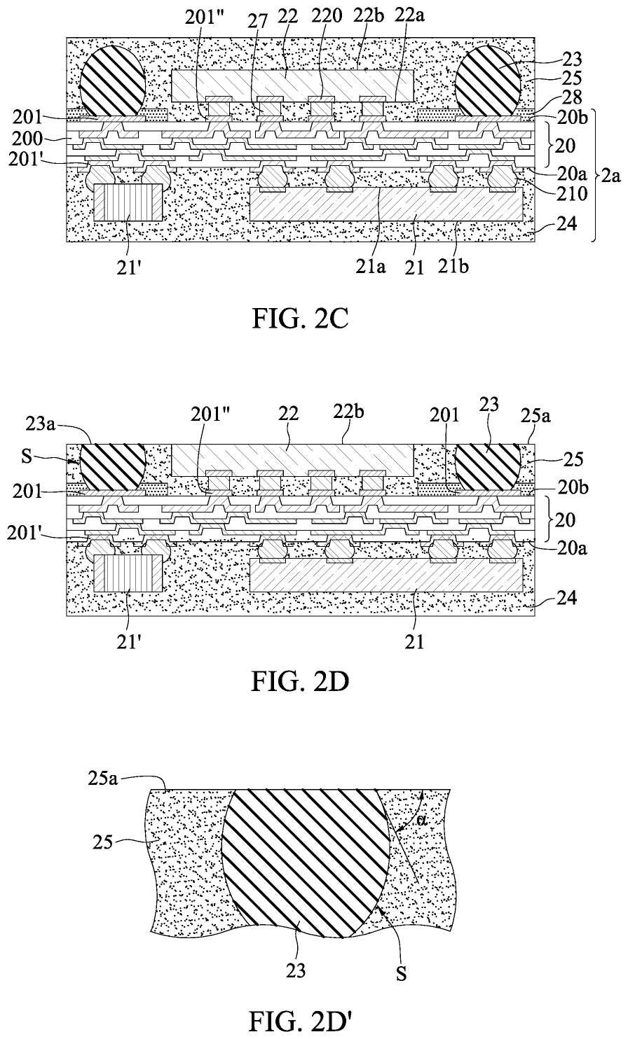

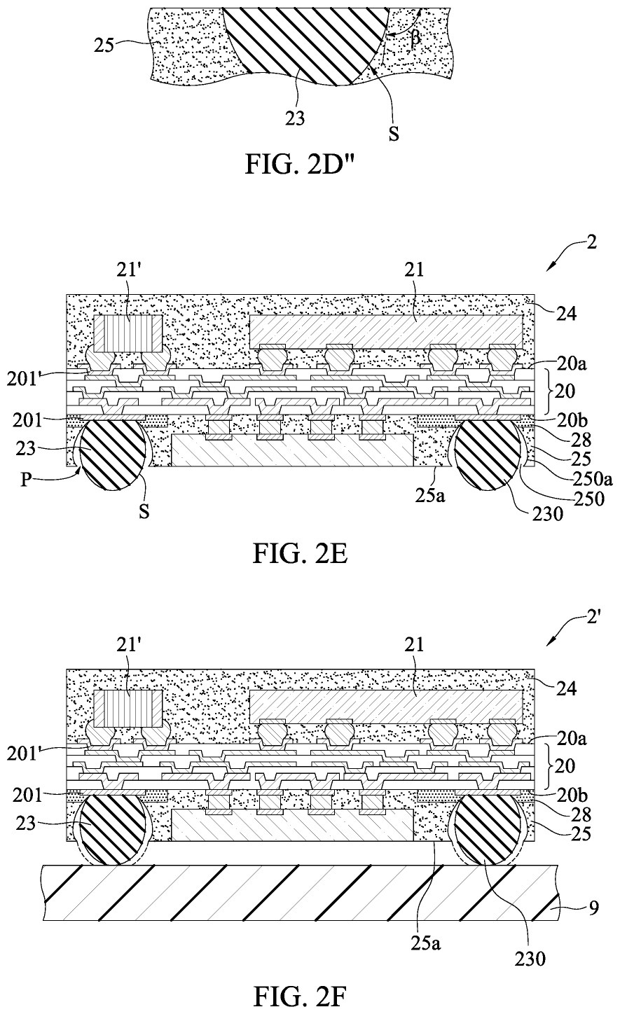

FIGS. 2A to 2E are cross-sectional views illustrating a method for fabricating an electronic structure of a first embodiment according to the present disclosure.

As shown in FIG. 2A, an electronic component 2a is provided, comprising a carrier 20, at least one first side electronic component 21, 21′, and an encapsulating layer 24.

In an embodiment, the electronic component 2a can be fabricated by any one of a variety of methods.

The carrier 20 comprises a first side 20a and a second side 20b opposing the first side 20a. In an embodiment, the carrier 20 is a packaging substrate having a core layer and a circuit structure or a coreless circuit structure. The carrier 20 includes at least one dielectric layer 200 and circuit layers 201, 201′ and 201″ bonded to the dielectric layer 200. In an embodiment, the coreless circuit structure is fabricated in a redistribution layer (RDL) method. In an embodiment, the circuit layers 201, 201′ and 201″ are formed of copper. In another embodiment, the dielectric layer 200 is formed of Polybenzoxazole (PBO), Polyimide (PI), or Prepreg (PP). In yet another embodiment, the carrier 20 can be a carrying unit, such as an interposer, that can carry an electronic component, such as a chip.

The first side electronic component 21, 21′ is bonded onto the first side 20a of the carrier 20. In an embodiment, the first side electronic component 21, 21′ is an active component, such as a semiconductor chip, a passive element, such as a resistor, a capacitor and an inductor, or a combination thereof. In an embodiment, the first side electronic component 21 is a semiconductor chip, which has an active surface 21a and an inactive surface 21b opposing the active surface 21a, and the active surface 21a has a plurality of electrode pads 210 electrically connected to the circuit layers 201′ in a flip-chip manner (via conductive bumps 26 shown in the figure). In another embodiment, the first side electronic component 21 is electrically connected via a plurality of solder wires (not shown) to the circuit layers 201′ in a wire bonding manner. In yet another embodiment, the first side electronic component 21 is in direct contact with the circuit layers 201′. In an embodiment, the first side electronic component 21′ is a passive element, which is electrically connected via the conductive bumps 26 to the circuit layers 201′. The first side electronic component 21, 21′ can be electrically connected to the circuit layers in other manner.

The encapsulating layer 24 is formed on the first side 20a of the carrier 20 and encapsulates the first side electronic component 21, 21′. In an embodiment, the encapsulating layer 24 is formed of an insulating material, such as polyimide (PI), a dry film, epoxy, a molding compound and epoxy, and can be formed on the first side 20a of the carrier 20 by a lamination or molding method.

The encapsulating layer 24 encapsulates the inactive surface 21b of the first side electronic component 21. As shown in FIG. 2A′, the encapsulating layer 24′ has a surface flush with the inactive surface 21b of the first side electronic component 21, and the inactive surface 21b of the first side electronic component 21 is exposed from the encapsulating layer 24′.

As shown in FIG. 2B, at least one second side electronic component 22 is disposed on the second side 20b of the carrier 20, and a plurality of conductive elements 23 are disposed on the circuit layers 201 of the second side 20b of the carrier 20.

In an embodiment, the second side electronic component 22 is an active component, such as a semiconductor chip, a passive element, such as a resistor, a capacitor or an inductor, or a combination thereof. In an embodiment, the second side electronic component 22 is a semiconductor chip, which has an active surface 22a and an inactive surface 22b opposing the active surface 22a, the active surface 22a has a plurality of electrode pads 220, and the second side electronic component 22 is electrically connected via electrode pads 220 (via conductive bumps 27 shown in the figure) to the circuit layers 201″ in a flip-chip manner. In another embodiment, the second side electronic component 22 is electrically connected via a plurality of solder wires (not shown) to the circuit layers 201″ in a wire bonding manner. In yet another embodiment, the second side electronic component 22 is in direct contact with the circuit layers 201″. The second side electronic component 22 can be electrically connected to the circuit layers in other manners.

In an embodiment, a non-metal material, such as a solder resist (e.g., a solder mask), an underfill, or a combination thereof, is first formed on the second side 20b of the carrier 20 to act as a protection layer 28, a portion of the protection layer 28 is then removed to form an opening 280 that is exposed from a portion of the second side 20b of the carrier 20, and the second side electronic component 22 is disposed in the opening 280 and electrically connected to the circuit layers 201″. In another embodiment, the protection layer 28 is formed on a portion of the circuit layers 201 on the second side 20b of the carrier 20 by a patterning molding method, with a portion of the second side 20b of the carrier 20 being exposed.

In an embodiment, the conductive element 23 is a solder ball, such as a tin ball, that has a continuous ball surface S (e.g., circular arc-shaped). In another embodiment, a plurality of holes 281 are formed on the protection layer 28 to expose a portion of the circuit layer 201 on the second side 20b of the carrier 20, and the conductive elements 23 are bonded (e.g., fused) to the circuit layer 201 in the holes 281, allowing the conductive elements 23 to be electrically connected to the circuit layers 201.

In an embodiment, the active surface 21a of the first side electronic component 21 faces the active surface 22a of the second side electronic component 22.

As shown in FIG. 2C, an encapsulating layer 25 is formed on the second side 20b of the carrier 20 and encapsulates the second side electronic component 22, the conductive elements 23, the conductive bumps 27 and the protection layer 28.

In an embodiment, the encapsulating layer 25 is an insulation material, such as PI, a dry film, epoxy or epoxy of molding compound, and can be formed on the second side 20b of the carrier 20 by a lamination or molding method. In another embodiment, the encapsulating layer 25 and the protection layer 28 are made of different materials.

The encapsulating layer 25 and the encapsulating layer 24 can be made of same or different material.

As shown in FIG. 2D, a portion of the encapsulating layer 25 and a portion of conductive elements 23 are removed by a leveling process, such as a grinding process, allowing a surface 25a on an upper side of the encapsulating layer 25 to be flush with end surfaces 23a of the conductive elements 23 and the conductive elements 23 to be exposed from the surface 25a of the encapsulating layer 25.

In an embodiment, since the conductive elements 23 have a continuous ball surface S, an interface of the encapsulating layer 25 with the conductive elements 23 also has the ball surface S (e.g., circular arc-shaped).

In an embodiment, the surface 25a on the upper side of the encapsulating layer 25 can also be flush with the inactive surface 22b of the second side electronic component 22, allowing the inactive surface 22b of the second side electronic component 22 to be exposed from the encapsulating layer 25.

As shown in FIG. 2E, a heating process, such as a reflow process, is performed, in which the conductive elements 23 have a continuous ball surface S, and the conductive elements 23 in the reflow process, via the cohesion of the conductive elements 23 (a solder tin material), allow the conductive elements 23 embedded in the encapsulating layer 25 to contract inward and protrude outward to the surface 25a of the encapsulating layer 25 to form protruding portions 230, and allow a gap P to be formed between the conductive elements 23 and the encapsulating layer 25 (i.e. the conductive elements 23 contract inward and thus making the encapsulating layer 25, which is in close contact with the conductive elements 23 originally, to form recessed portions 250 having walls 250a in the encapsulating layer 25, and the walls 250a are in the shape of the continuous ball surface S of the conductive elements 23 before contracting inward), so as to form the electronic structure 2 according to the present disclosure.

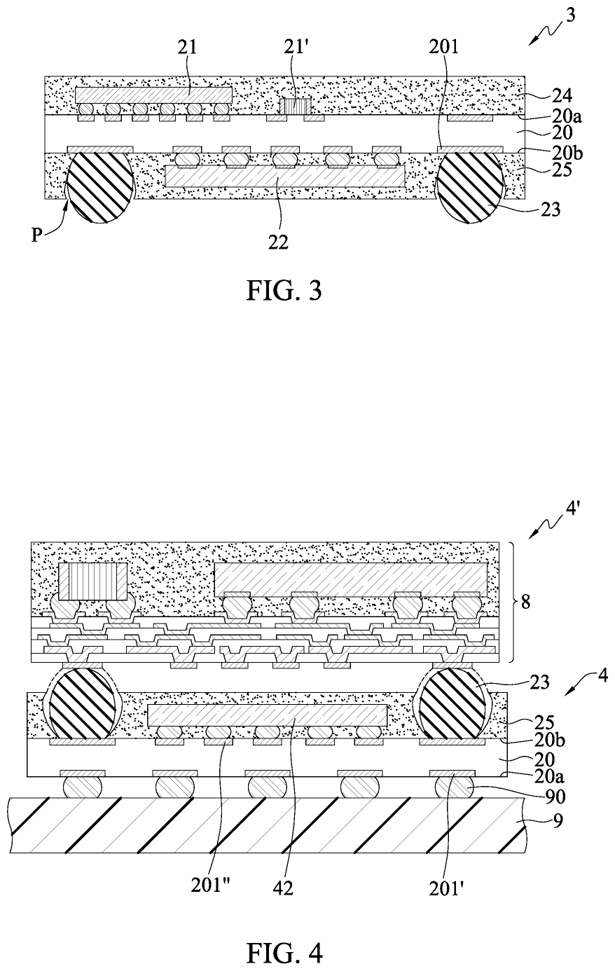

The size of the gap P can be controlled by controlling the time, temperature, etc. of the reflow process, allowing the conductive elements 23 to be in no contact with the encapsulating layer 25 (e.g., the electronic structure 2 shown in FIG. 2E), or allowing the conductive elements 23 to be in partial contact with the encapsulating layer 25 (e.g., the electronic structure 3 shown in FIG. 3), to strengthen the stability and reliability of positioning of the conductive elements 23.

In subsequent processes, the conductive elements 23 can be mounted in a reflow process, for example, with a circuit board 9 (e.g., a mother board) shown in FIG. 2F, a packaging structure or an electronic device having another structure (e.g., another chip), to form another electronic structure 2′. After the electronic structure 2 is mounted with another electronic device, the gap P may be filled completely and gone (as indicated by the dashed line shown in FIG. 2F) because of the reflowing process or the tin addition of the another electronic device.

In the method according to the present disclosure, by the interface of the encapsulating layer 25 in contact with the conductive elements 23 has a continuous ball surface S; the end surfaces 23a of the conductive elements 23 are exposed from the encapsulating layer 25, the conductive elements 23 protrude outward and are formed with the protruding portions 230 protruding from the surface 25a of the encapsulating layer 25 through a heating process, such as the reflow process, by using the cohesion of the conductive elements 23 for an external electronic device to be mounted thereon. The cohesion allows the conductive elements 23 to contract inward and the recessed portions 250 are formed between the conductive elements 23 and the surrounding encapsulating layer 25; and the walls 250a of the recessed portions 250 have cross sections in the shape of circular arcs substantially in a top-to-bottom direction (corresponding to the continuous ball surface S of the conductive elements 23 before contracting inward), so as to extend a solder climbing distance between the recessed portions 250 and neighboring solder balls, and avoid the bridging problem when the electronic structure 2 is mounted with an external electronic device via the conductive elements 23.

The continuous ball surface S where neighbors the surface 25a of the encapsulating layer 25 has an undercut shape (as shown in FIG. 2D′, an edge angle α is less than or equal to 90 degrees), and the undercut shape can effectively secure the flux used to clean and wet the conductive elements 23 in the reflow process, allowing the flux to clean and wet the conductive elements 23 efficiently. Compared with the laser holes of the prior art, the method according to the present disclosure will not generate waste pieces of the encapsulating layer 25, and can ensure that the conductive elements 23 to effectively contact and bonded with the circuit layers 201 and prevent a ball-falling situation.

During a leveling process (e.g., a grinding process shown in FIG. 2D), the amount of the encapsulating layer 25 and the conductive elements 23 to be removed can be adjusted, such that the edge angle β of the continuous ball surface S of the conductive elements 23 adjacent the surface 25a of the encapsulating layer 25 is greater than or equal to 90 degrees, as shown in FIG. 2D″.

It should be understood that an electronic component can be disposed on at least one of the first side 20a and the second side 20b of the carrier 20. In an embodiment, at least one electronic component 42 is disposed on the first side 20a or the second side 20b of the carrier 20, such as the electronic structure 4 shown in FIG. 4. In an embodiment, the electronic component 42 is bonded to the second side 20b of the carrier 20, and is an active element, such as a semiconductor chip, a passive element, such as a resistor, a capacitor or an inductor, or a combination thereof. In an embodiment, the electronic component 42 is a semiconductor chip and is electrically connected to the circuit layers 201″ in a flip-chip manner or other manners. In an embodiment, the electronic structure 4 is mounted with an electronic device of another package 8 or a chip via the conductive elements 23, and the circuit layers 201′ on the first side 20a of the carrier 20 is mounted via a plurality of solder tin materials 90 with an electronic device, such as a circuit board 9, to form another electronic structure 4′. After the electronic structure 4 is mounted with another electronic device, the gap P may be filled completely and gone (as indicated by the dashed line shown in FIG. 4) because of the reflowing process or the tin addition of the another electronic device.

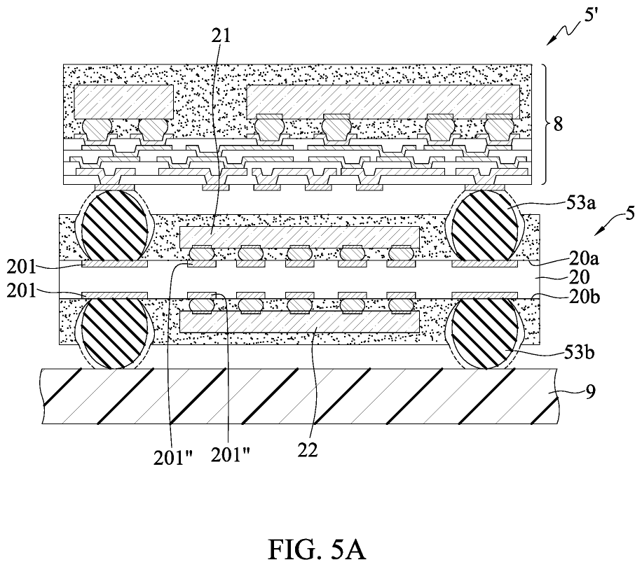

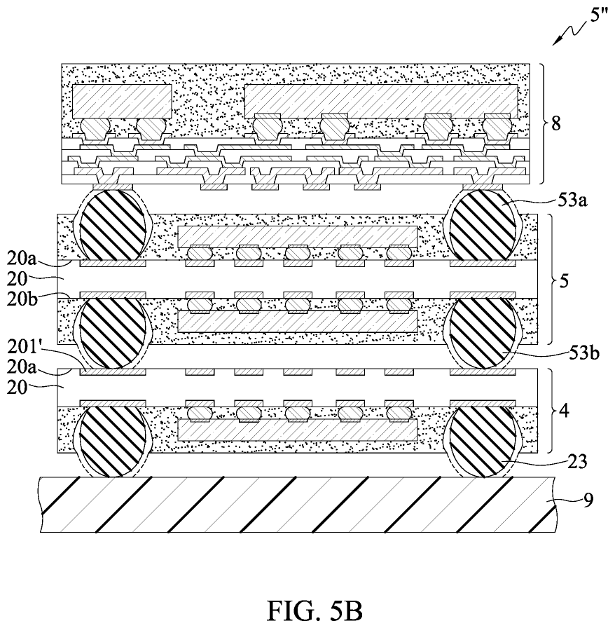

Conductive elements can be formed on at least one of the first side 20a and the second side 20b of the carrier 20 on demands. In an embodiment, such as the electronic structure 5 shown in FIG. 5A, first conductive elements 53a and second conductive elements 53b are formed on the first side 20a and the second side 20b of the carrier 20 respectively, the electronic structure 5 is mounted with an electronic device, such as another package 8 or a chip, via the first conductive elements 53a, and the second conductive elements 53b are mounted with an electronic device, such as a circuit board 9, to form another electronic structure 5′. After the electronic structure 5 is mounted with another electronic device, the gap P may be filled completely and gone (as indicated by the dashed line shown in FIG. 5A) because of the reflowing process or the tin addition of the another electronic device.

In an embodiment, two electronic structures can be stacked on each other, as shown in FIG. 5B. In another embodiment, the electronic structure 5 of FIG. 5A is stacked through its second conductive elements 53b and bonded on the circuit layers 201′ on the first side 20a of the carrier 20 of the electronic structure 4 of FIG. 4, and the electronic structure 4 is mounted through its conductive elements 23 onto an electronic device, such as the circuit board 9, to form another electronic structure 5″. After the electronic structure 4, 5 is mounted with another electronic device, the gap P may be filled completely and gone (as indicated by the dashed line shown in FIG. 5B) because of the reflowing process or the tin addition of the another electronic device.

The present disclosure further provides an electronic structure 2, 3, 4, 5, which comprises: a carrier 20, at least one electronic component 42 (or a first side electronic component 21, 21′ and a second side electronic component 22), a plurality of conductive elements 23 (or first conductive elements 53a and second conductive elements 53b), and an encapsulating layer 25 (the encapsulating layer 24 can be considered as the encapsulating layer 25).

The carrier 20 has a first side 20a and a second side 20b opposing the first side 20a, and is disposed with at least one circuit layers 201, 201′, 201″.

The electronic component 42 (or the first side electronic component 21, 21′ and the second side electronic component 22) is disposed on the first side 20a and/or the second side 20b of the carrier 20 and electrically connected to the circuit layers 201′, 201″.

The conductive elements 23 (or the first conductive elements 53a and the second conductive elements 53b) are bonded onto the circuit layers 201.

The encapsulating layer 25 is formed on the carrier 20 and encapsulates the electronic component 42 (or the second side electronic component 22), protruding portions 230 of the conductive elements 23 (or the first conductive elements 53a and the second conductive elements 53b) protrude from the encapsulating layer 25, and a gap P is formed between the conductive elements 23 and the encapsulating layer 25.

In an embodiment, the encapsulating layer 25 is formed with recessed portions 250, the conductive elements 23 (or the first conductive elements 53a and the second conductive elements 53b) are disposed in the recessed portions 250, a gap P is formed between the walls 250a of the recessed portions 250 and the conductive elements 23 (or the first conductive elements 53a and the second conductive elements 53b), the conductive elements 23 can be in partial or no contact with the wall 250a of the recessed portions 250. In another embodiment, the recessed portions 250 have edges in the shape of an undercut.

In an electronic structure and a method for fabricating the same according to the present disclosure, the end surfaces of the conductive elements are exposed from the encapsulating layer, the conductive elements are formed with protruding portions protruding outward from the encapsulating layer through a reflow process by using the cohesion of the conductive elements, for an external electronic device to be mounted thereon, the conductive elements contract inward and recessed portions are formed between the conductive elements and the encapsulating layer, the walls of the recessed portions are circular arc-shaped substantially, a solder climbing distance between the recessed portions and the neighboring solder balls is extended effectively, and the bridging problem can be avoided when the electronic structure is mounted via the conductive elements with an external electronic device. Therefore, the fabrication process is simplified, the cost is reduced, as compared with the laser process used in the prior art, and the falling problem of the conductive elements can be prevented.

The foregoing descriptions of the detailed embodiments are only illustrated to disclose the features and functions of the present disclosure and not restrictive of the scope of the present disclosure. It should be understood to those in the art that all modifications and variations according to the spirit and principle in the disclosure of the present disclosure should fall within the scope of the appended claims.

What is claimed is:

1. An electronic structure, comprising:
a carrier;
at least one electronic component mounted on and electrically connected to the carrier;
a plurality of conductive elements bonded onto the carrier; and
an encapsulating layer formed on the carrier, encapsulating the electronic component, and formed with a plurality of recessed portions corresponding in position to the plurality of conductive elements for receiving the plurality of conductive elements,
wherein the plurality of conductive elements have a plurality of protruding portions protruding from an outer surface of the encapsulating layer, a gap is formed between each of the plurality of conductive elements and one of the recessed portions corresponding thereto, and each of the plurality of recessed portions has a wall shaped substantially circular arc.

2. The electronic structure of claim 1, wherein the carrier has a first side and a second side opposing the first side, and the encapsulating layer and the plurality of conductive elements are disposed on the first side, the second side or a combination thereof.

3. The electronic structure of claim 1, wherein the conductive elements are in partial contact with the encapsulating layer.

4. The electronic structure of claim 1, wherein the conductive elements are in no contact with the encapsulating layer.

5. The electronic structure of claim 1, wherein the wall of each of the recessed portions is substantially a ball surface.

6. The electronic structure of claim 1, wherein each of the recessed portions is in a shape of an undercut at an outer edge of the encapsulating layer.

7. The electronic structure of claim 1, further comprising a circuit board or a packaging structure bonded to the protruding portions of the plurality of conductive elements.

8. A method for fabricating an electronic structure, comprising:
providing at least one electronic component on a carrier and electrically connecting the electronic component to the carrier;
forming a plurality of conductive elements on the carrier;
forming on the carrier an encapsulating layer that encapsulates the electronic component and the plurality of conductive elements;
removing a portion of the encapsulating layer and a portion of the plurality of conductive elements, allowing one end surface of each of the plurality of conductive elements to be exposed from the encapsulating layer; and
performing a reflow process, allowing the plurality of conductive elements to be formed with a plurality of protruding portions that protrude from an outer surface of the encapsulating layer, and the encapsulating layer to be formed with a plurality of recessed portions corresponding in position to the plurality of conductive elements, wherein a gap is formed between each of the plurality of conductive elements and one of the recessed portions corresponding thereto, and each of the plurality of recessed portions has a wall shaped substantially circular arc.

9. The method of claim 8, wherein the carrier has a first side and a second side opposing the first side, and the encapsulating layer and the plurality of conductive elements are disposed on the first side, the second side or a combination thereof.

10. The method of claim 8, wherein the conductive elements are in partial contact with the encapsulating layer.

11. The method of claim 8, wherein the conductive elements are in no contact with the encapsulating layer.

12. The method of claim 8, wherein the wall of each of the recessed portions is substantially a ball surface.

13. The method of claim 8, wherein each of the recessed portions is in a shape of an undercut at an outer edge of the encapsulating layer.

14. The method of claim 8, further comprising bonding a circuit board or a packaging structure onto the protruding portions of the plurality of conductive elements.
